(19) United States
(12) Patent Application Publication
(10) Pub. No.: US 2024/0186216 A1
(43) Pub. Date: Jun. 6, 2024

(54) INTEGRATION OF BORON ARSENIDE INTO POWER DEVICES AND SEMICONDUCTORS FOR THERMAL MANAGEMENT

(71) Applicant: THE REGENTS OF THE UNIVERSITY OF CALIFORNIA, Oakland, CA (US)

(72) Inventor: Yongjie HU, Los Angeles, CA (US)

(73) Assignee: THE REGENTS OF THE UNIVERSITY OF CALIFORNIA, Oakland, CA (US)

(21) Appl. No.: 18/553,151

(22) PCT Filed: Mar. 30, 2022
(86) PCT No.: PCT/US2022/022622

§ 371 Date: Sep. 28, 2023

Related U.S. Application Data
(60) Provisional application No. 63/167,877, filed on Mar. 30, 2021.

(51) Int. Cl. H01L 23/373; H01L 21/48; H01L 29/20; H01L 29/778

(52) U.S. Cl. CPC H01L 23/3736; H01L 21/4871; H01L 29/2003; H01L 29/7781

(57) ABSTRACT

The present embodiments relate generally to the integration of boron arsenide (BAs) and boron phosphide (BP) into semiconductor devices and electronics, including with all semiconductors (Si, Ge, InP, InAs, GaAs), metals, wide-bandgap gallium nitride (GaN, AIGaN, SiC), ultrawide-bandgap (AIN, c-BN, diamond, Ga2O3), HEMT devices, electronics, optoelectronics, photonics, or any power devices for high-performance thermal management. Embodiments successfully develop the first experimental integration and atomic structural characterization of GaN-on-BAs structure for passive cooling of GaN devices, GaN/AIGaN HEMT transistors, and RF technologies, and measured a high thermal boundary conductance of 250 MW/m2K. Importantly, experimental measurement of operating AIGaN/GaN HEMT devices confirms the substantially reduced hot spot temperature and clear advantage for using BAs versus diamond or silicon carbide as cooling substrate.

### CROSS-REFERENCE TO RELATED APPLICATIONS

The present application claims priority to U.S. Provisional Patent Application No. 63/167,877 filed Mar. 30, 2021, the contents of which are incorporated herein by reference in their entirety.

### STATEMENT REGARDING FEDERALLY SPONSORED RESEARCH

This invention was made with government support under Grant Number 1753393, awarded by the National Science Foundation. The government has certain rights in the invention.

### TECHNICAL FIELD

The present embodiments relate generally to electronics, and more particularly to integration of boron arsenide (BAs) and boron phosphide (BP) into semiconductors, electronics, and any power devices for high-performance thermal management.

### BACKGROUND

Future power, sensor, and communication systems require higher performance (e.g., output power) per unit area to meet mission requirements in increasingly congested and contested electromagnetic environments. Wide band gap (WBG) materials such as GaN technology provides a leap ahead in capability over legacy Si and GaAs radio frequency (RF) device technology; the Ultra Wide BandGap (UWBG) semiconductors (e.g., AlN, cBN, diamond, Ga₂O₃) show promise as the next leap in RF electronics. However, these materials and associated devices are in their infancy. For example, among potential issues, thermal management is a serious technology challenge associated with high power and expected to be even more serious for WBG and UWBG RF devices. Currently, in all power systems ranging from laptops, smart phones, data servers, to electric vehicles and radar communications, enormous waste heat dissipates from the hot spot to heat sink across a series of thermal resistances of device layers and their interfaces. Ridiculously, the power density in current high-power transistors is exceeding that of the Sun's surface. As a result, the device operation characteristics and energy efficiency can be largely degraded by a large thermal resistance and a rising hot spot temperature. The maximum output power is strongly limited by the high channel temperature and Joule heating, which degrades device performance and reliability.

It is against this backdrop that the present Applicant sought a technological solution to these and other issues rooted in this technology to advance the state of the art.

### SUMMARY

According to certain aspects, the present disclosure relates to the development of semiconductors, WBG and UWBG device structures (e.g., novel heterostructures), and engineering/fabricating WBG and UWBG electronics and RF (microwave/millimeter wave) devices. Technology advances include material synthesis (epitaxial growth, growth techniques and characterization, materials/defect engineering), physics-based device design, contact engineering, wafer bonding, device layer structures, interconnections, 3D architectures, surface and interface engineering, integral thermal management, high temperature operation, robustness, heterogeneous integration with other devices/materials systems, and other functionality/domains of WBG and UWBG materials/structures, including electronics, optoelectronics, optical, quantum, acoustic, mechanical, multi-ferroic, and others.

### BRIEF DESCRIPTION OF THE DRAWINGS

These and other aspects and features of the present embodiments will become apparent to those ordinarily skilled in the art upon review of the following description of specific embodiments in conjunction with the accompanying figures, wherein:

FIG. 1a is a schematic illustrating example heat dissipation and thermal boundary resistance (TBR) at the interfaces in microchip packaging.

FIG. 1b illustrates aspects of the relationship TBR=ΔT/Q, where ΔT and Q are the temperature drop and heat flux across the interface, respectively. FIG. 1c illustrates example room temperature thermal conductivities and Debye temperatures of representative metals, semiconductors, and HTC materials.

FIG. 2a is a schematic of one example time-domain thermoreflectance (TDTR) measurement set-up. Blue and orange routes represent pump and probe laser beams.

FIG. 2b illustrates aspects of BAs and BP as cooling substrate for metal films; in particular, FIG. 2b illustrates a cross-section SEM image of an example sample in which a top layer is aluminum film and the bottom layer is BAs.

FIG. 2c is a graph illustrating typical TDTR experimental data versus time (circles), fitted to the thermal transport model (solid lines). Calculated curves (dashed lines) with the thermal boundary conductance changed by ±10% of the best values to illustrate measurement accuracy.

FIGS. 2d and 2e are graphs illustrating example experimental results for the temperature-dependent thermal boundary conductance between varied metals with BAs and BP, respectively.

FIG. 3a is a schematic illustrating an example of phonon transport with mode specific transmission (t) and reflection probability (r) at the interface.

FIG. 3b is a graph illustrating example phonon dispersion relationships (left) and density of states (right) of BAs, BP, Diamond, Al, Pt, Au calculated from DFT (lines) in comparison with neutron scattering and Raman scattering experiments.

FIG. 3c is a graph illustrating example experimentally measured thermal boundary conductance (dots) of aluminum-HTC interfaces in comparison to calculations (lines), considering temperature dependence and different modeling methods.

FIG. 4a are example cross-section SEM (left) and high-resolution TEM (right) images of a typical sample, showing atomically resolved interface.

FIG. 4b is a graph illustrating results of example simulations of the hot spot temperatures for the two best thermal conductors (BAs and diamond), as a function of heating sizes from 100 μm to 100 nm. Inset, schematics of transport physics and the simulation domain, including a 0.8 μm thick GaN layer on the top of a 100 μm thick cooling substrate. All simulations inputs are from experimental measurements and ab initio calculations. The comparison from Fourier's heat conduction law (dashed lines) and spectral-dependent Boltzmann transport equation (solid lines), quantifies the transition from diffusive to ballistic thermal transport (insets). The size-dependent hot spot temperature results, indicate that BAs has a superior performance for nanoscale thermal management, owing to its both high thermal conductivity and thermal boundary conductance.

FIGS. 4c and 4d illustrate example aspects of experimental measurements of the hot spot temperature rise in operating AlGaN/GaN HEMTs as a function of transistor power densities, with different cooling substrates: BAs, diamond, and SiC. All devices shared the same geometry: two fingers, 100 μm-wide and 34 μm gate pitch.

FIG. 4c is an example SEM image of the fabricated HEMT device. Scale bar, 20 μm.

FIG. 4d is a graph illustrating the GaN temperature as measured using Raman spectroscopy on the drain side at a lateral distance of 0.5 μm from the T-gate edge, for transistors on a GaN-on-BAs wafer, as well as a reference GaN-on-diamond wafer and GaN-on-SiC wafer. Data for diamond and SiC substrates are adapted from the reference.

### DETAILED DESCRIPTION

The present embodiments will now be described in detail with reference to the drawings, which are provided as illustrative examples of the embodiments so as to enable those skilled in the art to practice the embodiments and alternatives apparent to those skilled in the art. Notably, the figures and examples below are not meant to limit the scope of the present embodiments to a single embodiment, but other embodiments are possible by way of interchange of some or all of the described or illustrated elements. Moreover, where certain elements of the present embodiments can be partially or fully implemented using known components, only those portions of such known components that are necessary for an understanding of the present embodiments will be described, and detailed descriptions of other portions of such known components will be omitted so as not to obscure the present embodiments. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the present disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present embodiments encompass present and future known equivalents to the known components referred to herein by way of illustration.

As set forth above, thermal management has been a serious technology hurdle in semiconductor industry for decades. In most modern electronic systems ranging from laptops, smart phones, data servers, to electric vehicles and radar communications, enormous waste heat dissipates from the hot spot to heat sink across a series of thermal resistance of device layers and their interfaces. As a result, the device operation characteristics and energy efficiency can be strongly degraded by a large thermal resistance and a rising hot spot temperature. Recent research focuses on improving heat dissipation by using high thermal conductivity (HTC) substrates to replace lower conductivity materials (silicon carbide, silicon, and sapphire) to reduce the overall spreading thermal resistance. The key challenge for high-performance thermal management is to achieve the combination of a HTC and a low thermal boundary resistance (TBR) near electronics junction interfaces. Currently, copper, SiC, and diamond are the best developed prototype HTC material for high performance power cooling; importantly it has been integrated with wide-bandgap semiconductors and shown lower hot spot temperatures in GaN-diamond devices than traditional RF systems. However, a poor thermal conductance was found at the GaN-diamond or GaN-SiC interfaces and severely compromised the application promise of diamond or SiC for thermal management. Other classical HTC materials have so far been limited by thermal properties and intrinsic issues. Cubic boron nitride suffers synthesis challenge that usually requires high temperature and high pressure, slow growth rate, high cost, and difficulty in integration with semiconductors. Graphite is highly anisotropic and mechanically soft due to weak cross-plane van der Waals bonding. Nanomaterials such as graphene and nanotubes can be highly conducting for individual materials, but have degraded thermal conductivity when integrated into practical sizes due to ambient interactions and disorder scattering.

Meanwhile, the urgent need to tackle thermal management challenge has called for the development of new HTC materials. Most recently, building on ab initio theoretical calculations, a new class of boron compound semiconductors, including boron phosphide (BP) and boron arsenide (BAs), has been experimentally realized and verified with record high thermal conductivity. In particular, one recent approach has measured an isotropic thermal conductivity of 1300 W/mK in BAs and 500 W/mK in BP, beyond that of most known heat conductors. The thermal conductivity of BAs is over three times that of the industrial HTC standards such as copper and SiC (both around 400 W/mK) and twice that of cubic boron nitride.

Moreover, as desired for device integration, the mechanical and thermophysical properties of BAs have been experimentally verified to be highly compatible with power semiconductors. With very high application promise, the integration and characterization of these new HTC materials with other materials layers is critically important towards their future device implementation, however has remained to be explored.

In this disclosure, the present Applicant reports the integration and interface characterizations of these new HTC semiconductors with prototype metal and semiconductor materials. As verified through ultrafast spectroscopy experiment and atomistic phonon theory, BAs and BP enable an unprecedented combination of a HTC and a low TBR due to their unique phonon band structures. The present Applicant demonstrated the first GaN-on-Bas structure using metamorphic heteroepitaxy growth for passive cooling of RF systems, and measured its high thermal boundary conductance of 250 MW/m²K, over 8 times that of diamond.

Comparison of the device-level hot spot temperatures of GaN transistors as a function of length scaling from 100 μm to 100 nm in both diffusive and ballistic transport regimes, shows that the thermal management performance of BAs substantially exceeds that of diamond, silicon carbide (SiC) and the state of the art. Importantly, the present Applicant performed direct experimental measurements of operational AlGaN/GaN high-electron-mobility transistors (HEMTs) and verified the superior cooling performance of BAs to diamond and SiC.

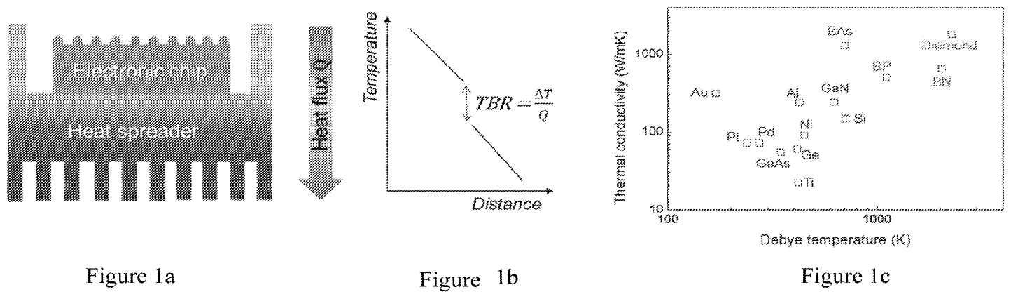

FIGS. 1a to 1c illustrate aspects of thermal management using integrated high thermal conductivity (HTC) materials (BAs and BP) as cooling substrate to improve heat dissipation.

Fundamentally, thermal boundary resistance (TBR) measures an interface's resistance to thermal flow and is limited by the scattering of energy carriers from both sides of the interface. The earliest discovery of TBR can be traced back to 1941 and the Kapitza resistance between liquid helium and solids; thereafter, TBR was confirmed to exist at all heterogeneous interfaces regardless of the atomic perfection. For semiconductor device interfaces such as the example shown in FIG. 1a, despite intensive improvement on materials quality such as surface roughness and defects, the ultimate limit of TBR is usually dominated by the mismatch across the interface of atomistic vibrations, the quantum mechanical modes of which are defined as phonons. Under the classical Debye approximation, vibrational properties of materials is approximated as the linear phonon dispersion, and the maximum temperature of the highest phonon frequency is defined as the Debye temperature (Θ_{D}). Therefore, in the literature a simplified evaluation metric, which qualitatively estimates the overlap between phonon spectra, is to compare the Θ_{D}. Based on that, a smaller difference in Θ_{D} between materials across the interface expects a smaller TBR. FIG. 1b illustrates aspects of the relationships involved in TBR.

FIG. 1c shows the comparison of Θ_{D} for typical semiconductors, metals, and HTC materials. Based on this comparison, the present Applicant recognizes that most semiconductors (Si, Ge, GaAs, GaN) and metals (Al, Au, Ni, Pd, Pt, Ti) usually have a low Θ_{D} (e.g., below 700 K). However, the traditional prototype HTC materials, i.e. diamond and cubic BN, as a result of their large phonon group velocity, have a much higher Θ_{D} (over 2000 K). Indeed, despite the advantageous HTC of diamond or BN, literature studies have verified a large TBR for their interfaces after integration, which significantly compromises their application promise for thermal management. For example, the interface between diamond and GaN, has a mismatch in Θ_{D} over 1500 K, leading to TBR usually of ˜30 m²K/GW. In comparison, as shown in FIG. 1c, the Θ_{D} of BAs and BP is much lower; for example, BAs has a Θ_{D} of ˜700 K, which is roughly the same as semiconductors such as Si and GaN. Meanwhile, their HTC is comparable to diamond.

According to this estimation, Applicant recognizes that the new HTC materials BAs and BP hold high promise for TBR improvement upon integration; however, their interface integration and transport for thermal management application has yet to be explored. The present disclosure investigates heat dissipation performance and mechanisms at these interfaces through detailed materials characterizations, spectroscopy measurements, and phonon transport theory simulations.

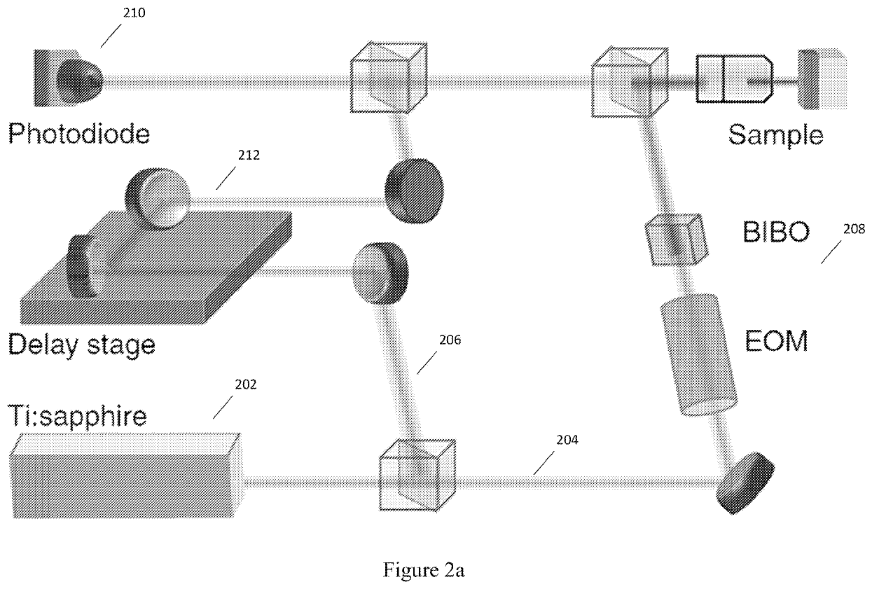

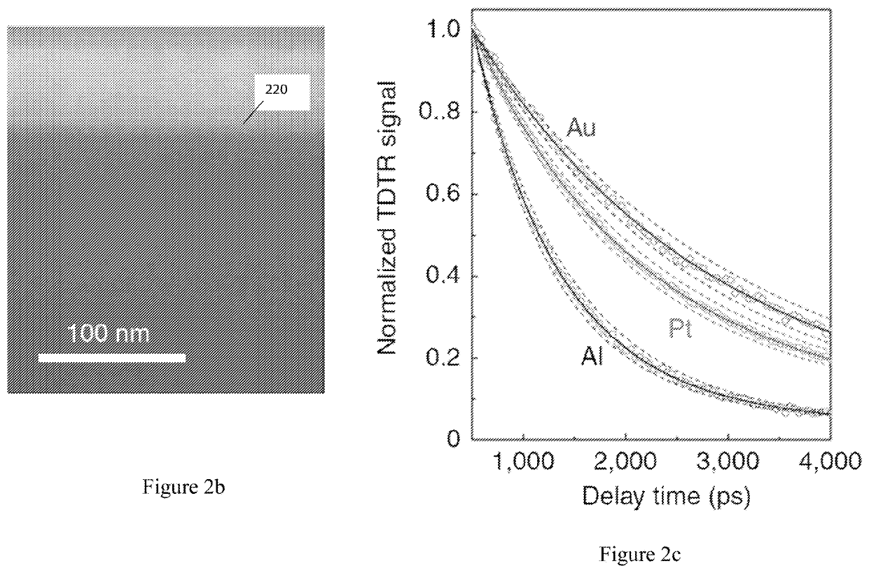

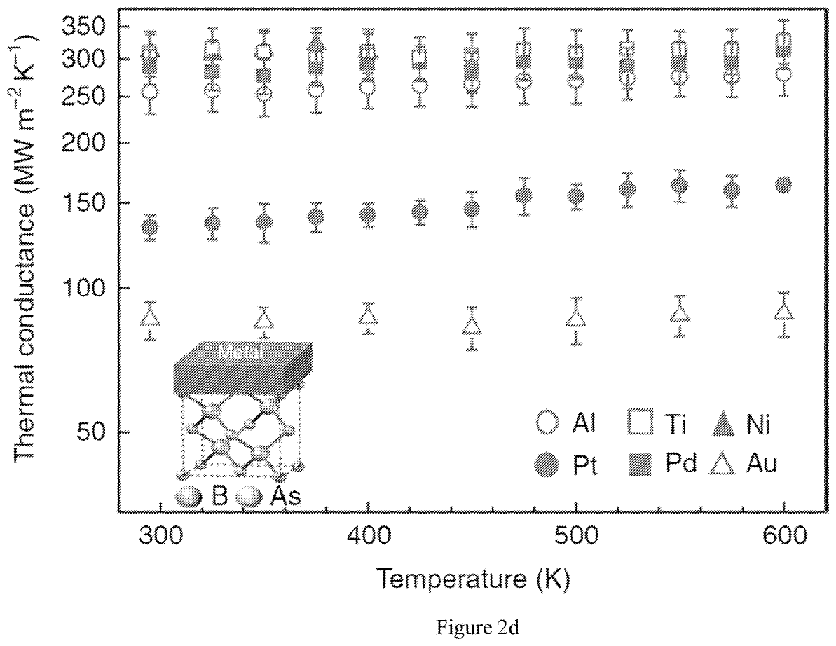

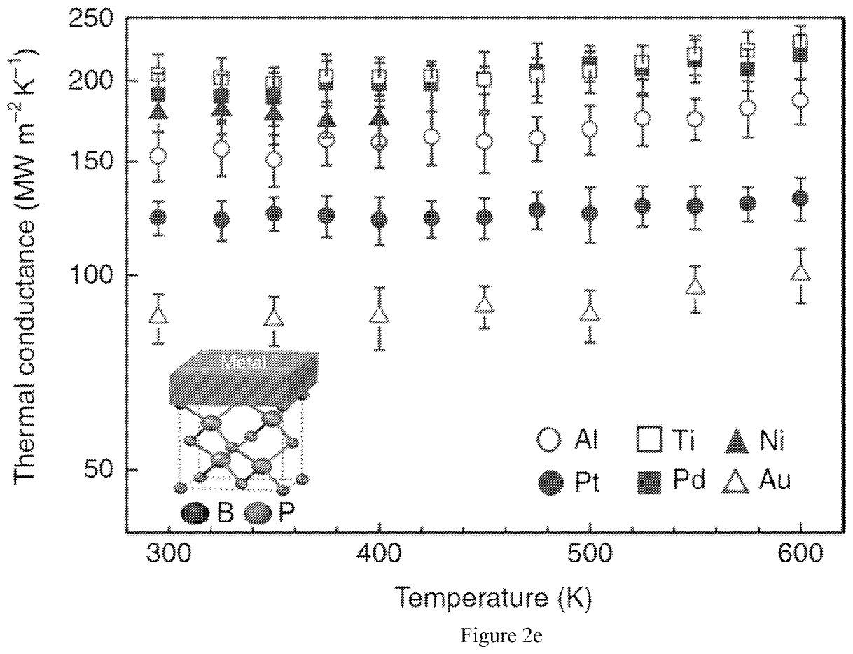

FIGS. 2a to 2e illustrate example aspects of metal-HTC interfaces and ultrafast optical spectroscopy measurements of temperature-dependent thermal boundary conductance according to embodiments.

The thermal transport was measured using ultrafast pump-probe spectroscopy based on the time domain thermoreflectance (TDTR) technique, illustrated in FIG. 2a. TDTR is well suited for the study as no physical contact is required with the sample and the measurement can precisely determine the TBR. In this setup, a femtosecond pulse laser with 80 MHz repetition rate is generated by a Ti:Sapphire optical cavity 202 and divided into pump 204 and probe 206 beams. The pump beam 204 doubles its frequency (i.e., at the wavelength of 400 nm) after passing through a second harmonic generator 208, and is used to thermally excite the sample surface. The probe beam, at the wavelength of 800 nm, is used to detect the sample temperature using photodiode 210. The time delay between pump and probe beams is precisely controlled by a mechanical delay stage 212 with a sub-picosecond resolution.

To determine TBR, the transient TDTR signal is detected and fitted to a multilayer thermal model (FIG. 2c). More details regarding TDTR and TBR measurements can be found in, for example, Kang, J. S. et al., “Experimental observation of high thermal conductivity in boron arsenide,” Science 578, 575-578 (2018); Li, M. et al., “Anisotropic Thermal Boundary Resistance across 2D Black Phosphorus: Experiment and Atomistic Modeling of Interfacial Energy,” Transport. Adv. Mater. 31, 1901021 (2019); Li, M. et al., “Anisotropic thermal conductivity measurement using a new Asymmetric-Beam Time-Domain Thermoreflectance (AB-TDTR) method,” Rev. Sci. Instrum. 89, 084901 (2018); and Kang, J. et al., “Intrinsic Low Thermal conductivity and Phonon Renormalization Due to Strong Anharmonicity of Single-Crystal Tin Selenide,” Nano Lett. 19, 4941-4948 (2019).

First measured was the thermal transport across the interfaces of the HTC materials with various metals. Metal films, including Al, Au, Ni, Pd, Pt, Ti, and Ni, are deposited on top of Bas and BP thin films using an electron beam evaporation technique to form a clean metal-HTC interface 220, as verified by cross-section scanning electron microscopy (SEM) (FIG. 2b).

Experimental measurement results of the temperature dependent thermal boundary conductance (G), i.e. the reciprocal value of TBR for Bas and BP are shown in FIGS. 2d and 2e, respectively. In general, metal interfaces with BAs and BP are measured with high thermal conductance. The value of G varies for each metal but has a similar trend between BAs and BP: For example, Au and Ti have the lowest and highest G values, respectively. As shown in FIG. 2d, the measured thermal boundary conductance values at room temperature between BAs and Au, Pt, Al, Pd, Ni, and Ti are 85, 133, 250, 290, 309, 310 MW/m²K, respectively. These values are slightly higher than that obtained with BP as shown in FIG. 2e, and as expected from the difference in Θ_{D}. From 300K to 600K, no significant temperature dependence is observed for G, indicating that a complete phonon excitation and a saturated phonon population are involved in the interface transport. It should be noted that the thermal boundary conductance of BAs and BP with metals are typically over 4× and 2.5× higher, respectively, than that of a metal-diamond interface, which verifies a high heat dissipation efficiency.

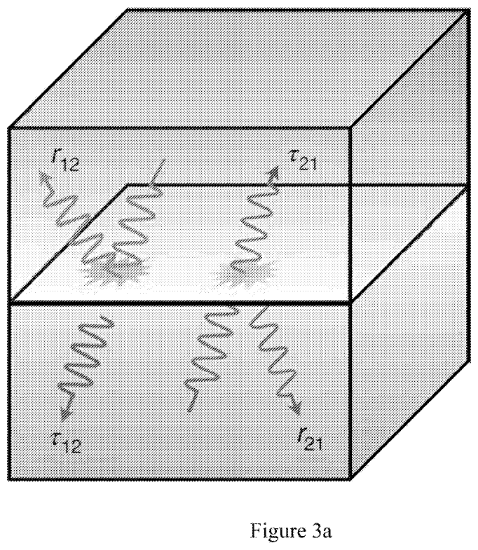

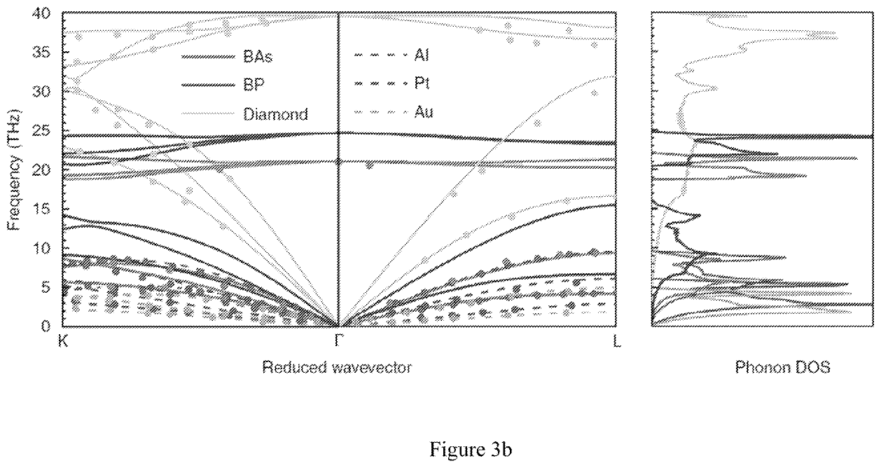

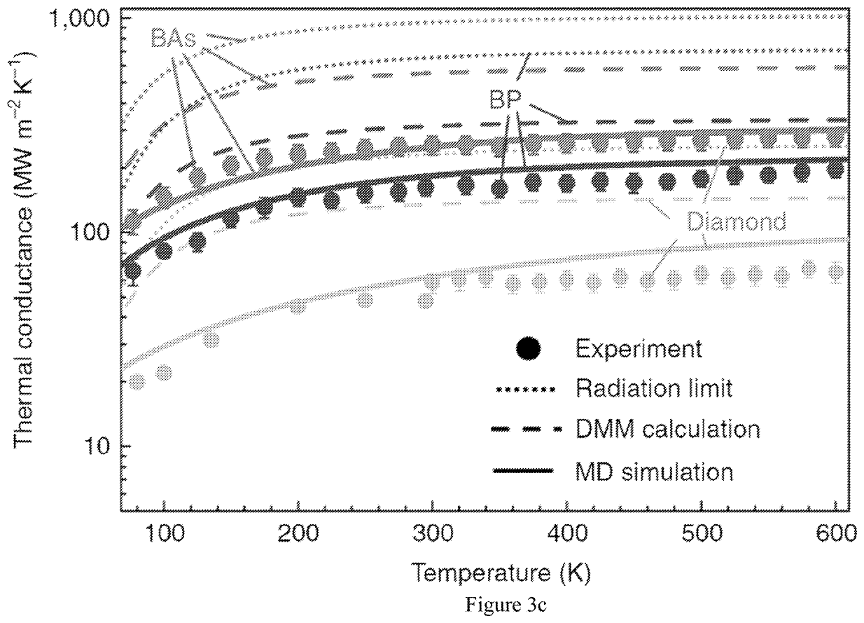

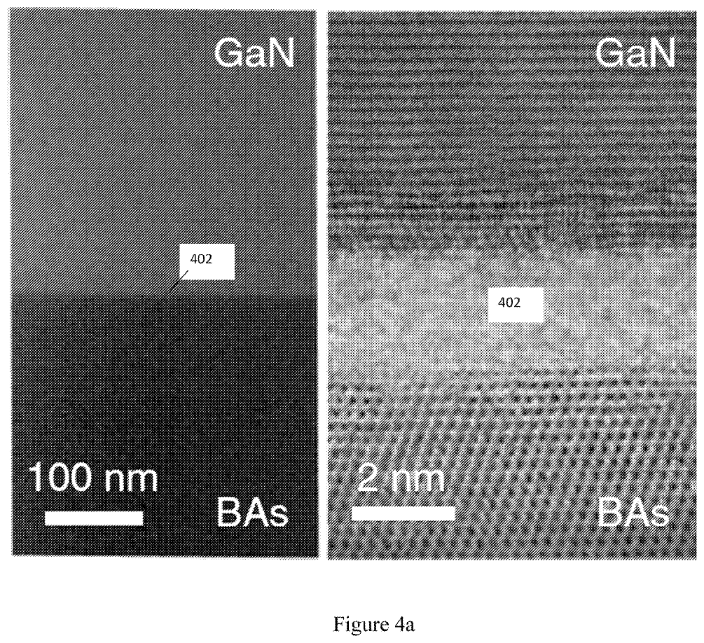

To understand the experimental results, performed were atomistic calculations to capture the phonon spectral contributions to the interfacial energy transport. FIGS. 3a to 3c illustrate example aspects of ab initio calculation of phonon band structures and atomistic modelling of phonon spectral contribution to the thermal boundary conductance according to embodiments.

Under the phonon picture, TBR can be understood as resulting from the breakdown of coherence of the mode-dependent phonon transport across the interfaces. As illustrated in FIG. 3a, when the incident phonons encounter the interface, partial transmission (i.e., partial reflection back) could happen, but with different probabilities for each phonon mode. In most literature, for simplicity, the dispersion relationship is usually approximated by a linear dispersion relationship (i.e., the Debye approximation). However, the Debye approximation oversimplifies the TBR calculation using a single phonon group velocity along each direction. Here, ab initio calculations were performed based on density functional theory (DFT) to obtain the full phonon band structures of the different materials as shown in FIG. 3b and construct the phonon-mode-dependent modeling of the interfacial thermal transport. The second-order interatomic force constants were calculated using the finite displacement method. For all the materials considered here, the projector augmented wave pseudopotential with the local density approximation was used. For each structure, a supercell with a 3×3×3 cubic unit cell with periodic condition was constructed for DFT calculations using Quantum Espresso package. A 12×12×12 Monkhorst-Pack mesh was used for the reciprocal space and the kinetic-energy cut-off for the plane-wave basis set was 600 eV. By displacing the atoms with a finite distance of 0.03 Å, the second order force constants were extracted with the Phono3py package. These calculated phonon band structures were compared with neutron scattering and Raman scattering experiments and show good consistency as shown in FIG. 3b. The phonon density of states (PDOS) were also calculated and plotted on the right side of FIG. 3b. Note that PDOS defines the number of available quantum states for each phonon energy. The PDOS overlap across the interface dictates TBR as it determines the probability to prepare phonons before incident on the interface and to accommodate phonons after transmission from the interface. Therefore, a larger PDOS overlap qualitatively indicates a lower TBR.

The results in FIG. 3b show that the dominant range of PDOS spans from 15 to 40 THz for diamond, and from 0 to 20 THz for BAs or BP. In comparison, the PDOS is mainly distributed between 0 and 10 THz for most metals. In particular, the cutoff acoustic frequencies are 32.0 THz in diamond, 16.1 THz in BP, 9.6 THz in BAs, 9.5 THz in Al, 6.1 THz in Pt, and 4.9 THz in Au. These PDOS spectra show that BAs overlaps best with most metals, followed by BP, and with diamond as the worst option. The comparison of PDOS further explains the improved TBR with BAs/BP versus diamond, as well as the variation between different metals, which is consistent with the experimental results shown in FIGS. 2d and 2e.

To understand the fundamental limit of the TBR, analytical calculations were developed by taking advantage of our ab initio derived phonon band structures. Under the Landauer-Buttiker formulation, the TBR is calculated based on the mode-dependent properties as:

$$\frac{1}{TBR} = G = \frac{1}{\text{?}} \text{?} {τ}_{12} ( k , i ) \text{?} dk \qquad ( 1 )$$

$$where {τ}_{AB} ( k , i ) \text{?} ω ( k , i ) , V ( k , i ) , f = \frac{1}{exp \text{?}}$$

$$\text{?} \text{indicates text missing or illegible when filed}$$

are the transmission coefficient, frequency, group velocity and equilibrium Bose-Einstein distribution function of phonons with wavevector k and polarization i. n is the unit vector normal to interface. The subscript indicates the material on side 1 or side 2 across the interface. The transmission coefficient term (τ₁₂(k,i)) is a key parameter to quantify how many phonons are reflected or allowed to transmit through the interface, as illustrated in FIG. 3a. First, consider the lower limit of TBR as when the transmission of all overlapping phonon modes reaches 100%, i.e., the Radiation limit. Under this Radiation limit, the phonon transport is similar to radiation heat transfer between blackbodies, so that all the emitted phonons from the one side of the interface would be accepted by the absorption side once the state of phonons are allowed into the absorption side.

Mathematically, the transmission coefficient would be unitary, i.e., τ₁₂(k, i)=1 if the frequency of the emitted phonon from side 1 is lower than the maximum phonon frequency in side 1. The maximum G values based on the Radiation limit, plotted as dotted lines in FIG. 3c, are 953 MW/m²K for an Al-BAS interface, 652 MW/m²K for an Al-BP interface, and 232 MW/m²K for an Al-diamond interface. As expected, the experimental results for the different interfaces follow the order predicted by the Radiation limit, but the experimental values are far below this maximum limit, as a full transmission cannot be achieved for practical interfaces. Alternatively, consider the diffuse scattering limit of TBR: all the phonons lose their memory after scattering at the interface and when re-emitted from the interface can originally be from either side of the interface, i.e., τ₁₂(k, i)=1−τ₂₁(k, i). By applying this physical constraint and considering the detailed balance of heat flux, the transmission coefficient can be calculated as:

$${τ}_{12} ( k , i ) = \frac{\text{?} \vert V ( k , j ) n \vert \text{?} dk}{\text{?} \vert V ( k , i ) n \vert \text{?} dk + \text{?} \vert V ( k , j ) n \vert \text{?} dk} \qquad ( 2 )$$

$$\text{?} \text{indicates text missing or illegible when filed}$$

where δ_{ω,ω(k,i)} is the Kronecker delta function. Note that the ab initio derived full phonon band structure from DFT calculations were used for the calculation and the results for the interfaces between Al and BAs, BP and diamond are plotted as dashed lines in FIG. 3c. It can be found that both the above analytical calculation limits (Radiation limit and the diffuse scattering) show a consistent trend with the experimental measurements, i.e., G_{Al-BAS}>G_{Al-BP}>G_{Al-diamond} over a wide (77 K to 600 K) temperature range. In particular, the G values between BAs and metals are clearly revealed to be much larger than that between diamond and metals, due to the better match in PDOS and the phonon group velocities from BAs. It was also noticed that these analytical predictions are (expectedly) higher than experimental results because inelastic scattering processes and anharmonicity such as multiple phonons scattering need to be included to better describe the interface transport, as discussed below.

To better quantify the phonon scattering and interface energy transport, numerical simulations were performed based on ab-initio molecular dynamics (MD) to calculate the TBRs. The interatomic potentials were first developed for the new materials, i.e. BAs and BP directly from quantum mechanical calculations based on ab initio MD determined atomic forces using potfit package. In the ab initio MD, Quantum Espresso was used to construct a supercell with a 4×4×4 cubic unit cell for BAs and BP with norm-conserving pseudopotentials in the localdensity approximation. The kinetic-energy cut-off for the plane-wave basis set was 1360 eV. The Tersoff and embedded atom method potential are used for diamond and Al. The interfacial interaction between Al and HTC materials were described using Lennard-Jones potential and the parameters were derived from the Lorentz-Berthelot rules. To minimize the mismatch at interface, the supercell size is 10×10×80 (Al) and 11×11×80 (diamond) for Al-diamond interface, 14×14×80 (Al) and 12×12×80 (BP) for Al-BP interface, 13×13×80 (Al) and 11×11×80 (BAs) for Al-BAS interface. The whole systems were relaxed under isothermal-isobaric ensemble at desired temperature and pressure for 5 ns, followed with relaxation under canonical ensemble for 3 ns and microcanonical ensemble for 2 ns with a time step of 0.5 fs. The MD simulations were performed with Large-scale Atomic/Molecular Massively Parallel Simulator (LAMMPS).

By setting anchor layers and thermal reservoirs at the two ends of the system, the steady-state temperature profile across the system under a constant heat flux can be obtained after 10 ns. The TBR values are determined from the heat flux and temperature drop at interface. The MD predicted TBRs for the interface with BAs, BP, and diamond are plotted in comparison with experimental results in FIG. 3c. Clearly, the MD predictions are in close to the experimental measurements; the good agreement by the MD predictions indicate that a more realistic interatomic interaction can better describe the phonons behaviors at interface, including the elastic phonon scattering, high-order anharmonicity and phonon mode conversion that such atomistic interactions dictate the macroscopic TBRs. More importantly, from the consistent trend between the Radiation limit, phonon diffuse scattering, and MD simulation, it can be concluded that the band structure of BAs facilitates efficient phonon transport across the interface and ensures its TBR to be intrinsically low.

As a further important step, the present Applicant demonstrated for the first time the experimental integration of BAs with a prototype high-power semiconductor, i.e., GaN, and report their record-high heat dissipation performance. Note that fundamentally the combination of a high thermal conductivity and a high thermal boundary conductance is needed to enable efficient heat dissipation. Recent progress has been made in integrating GaN with classical HTC materials (in particular diamond and SiC) for power cooling with focus on improving the near-junction lattice mismatch, defects, and the resulted thermal boundary resistance that limit the overall heat dissipation. For this new semiconducting HTC material BAs, to directly integrate BAs with GaN is challenging because crystal structures of BAs (zinc blende cubic) and GaN (wurtzite) are different, making it difficult to form epitaxial interfaces with minimum disorders.

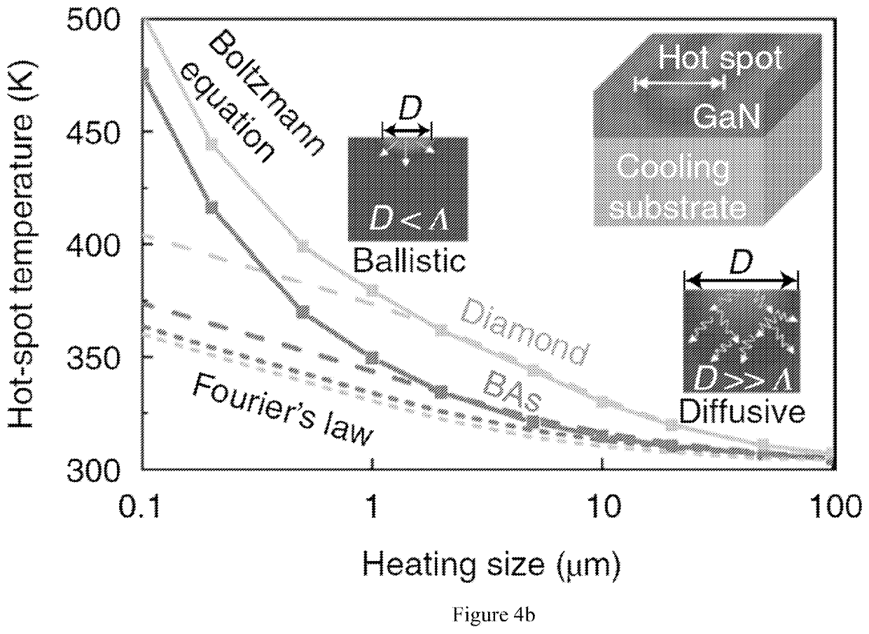

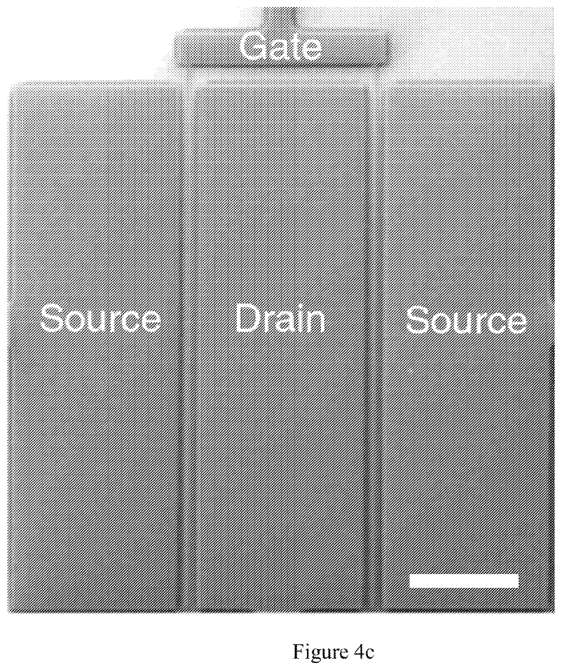

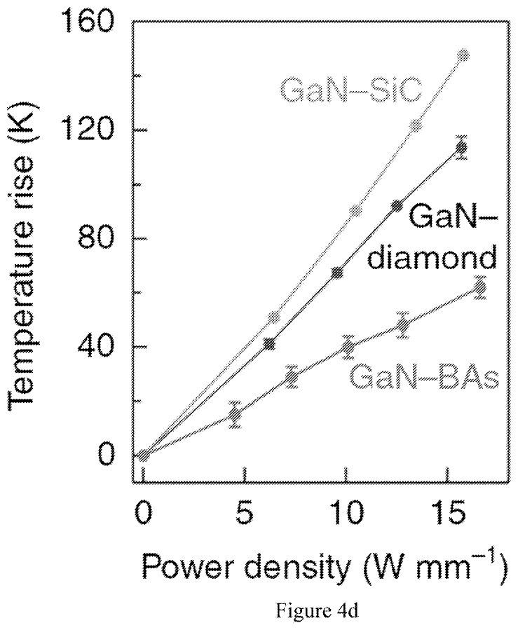

Also, BAs decomposes at about 1200 K, so low temperature crystal growth is required. Here, in order to get a high quality interface between BAs and GaN, the present Applicant applied metamorphic heteroepitaxy method to relax the strain: A thin layer of oxide was introduced as the adhesion layer in between, using atomic layer deposition technique. A follow-up treatment using oxygen plasma was used to activate interface bonds and the sample was annealed at 773K for 24 hours in vacuum. The heterogeneous interface was carefully verified by SEM and high-resolution transmission electron microscopy (HR-TEM): FIG. 4a shows an atomically clean and uniform GaN-BAs interface with a 2 nm interlayer aluminum oxide. The thermal boundary conductance of the high quality BAs-GaN interface was measured using TDTR to be ˜250 MW/m²K—Note that this conductance value is already over 8 times higher than that of the typical GaN-diamond interfaces. Moreover, considering that the oxide layer could serve as a barrier to scatter phonons and introduce an additional series resistance (e.g., ˜1.4 m²K/GW for 2 nm oxide, or 35% of the measured total resistance), the TBR of GaN-BAs interface could be subject to further enhancement through the optimization of the resistance contribution from the oxide interlayer.

To evaluate the device-level heat dissipation performance of BAs as a cooling substrate, the hot spot temperature was determined across a GaN-BAs interface as a function of various heating sizes from 100 μm to 100 nm. The heat dissipation performance of GaN-BAs device was compared with that of the current state-of-the-art GaN-diamond device, verifying the record-high performance. Considered was an exemplary device geometry involving GaN device layer on the top of BAs or diamond cooling substrate by using experimental data as the input and solving the heat conduction equation and the Boltzmann transport equation (BTE) (inset, FIG. 4b). A boundary line heat source with a fixed power (e.g., 10 W/mm) was placed on top of the GaN layer to serve as the hot spot, and the bottom of the substrate was fixed at room temperature. To study the size-dependent effect of the hot spot temperature, the width of the heat source was varied. Experimental data of TBR and thermal conductivity were used for these simulations. First simulated was a hot spot temperature by solving the heat conduction equation using the finite element method. In this case, thermal transport is considered as a diffusive process, where the heat flux is proportional to the temperature gradient following the Fourier's heat conduction law.

The classical diffusion theory describes the thermal transport process well when the characteristic length is far larger than the phonon mean free path, and is commonly used for engineering macroscopic devices. FIG. 4b shows the hot spot temperature calculated with the heat conduction equation. The hot spot temperature increases when the heater width decreases, due to the larger heating power density. To evaluate the effect from TBR, upon intentionally removing TBR in the simulation (dotted lines), it was found that, as expected due to its high thermal conductivity, diamond shows slightly advantage. However, TBR ubiquitously exists in practical devices. When TBR was included in the simulation (dashed lines), BAs clearly has a reduced hot spot temperature than diamond, supporting its superior performance in heat dissipation through the combination of a HTC and low TBR.

Moreover, also evaluated was the device performance under conditions where the ballistic transport takes place and the classical diffusion theory fails for nanoscale devices. With the shrinking of device sizes down below the phonon mean free paths, phonon transport would not experience scattering. In this case, the practical heat dissipation behaves more like radiation rather than diffusion, so the actual hot spot temperature will deviate from the prediction by the Fourier's law. Such ballistic thermal transport and phonon mean free path spectra of GaN, diamond, BAs and BP have all been experimentally measured and analyzed in recent studies by the present Applicant. Here, to capture the physics of thermal transport from the diffusive regime to the ballistic regime, the present Applicant solved the spectral-dependent Boltzmann transport equation considering mode-dependent phonon properties for the same device structure. The three-dimensional spectral-dependent BTE is given by:

δf/δt+v(ω,p)·∇f=f−f0/τ(ω,p) (3)

where f is the phonon distribution function, and f0 is the equilibrium Bose-Einstein distribution at the local temperature. v(ω, p) and t(ω, p) are respectively the phonon group velocity and the phonon relaxation time at a certain angular frequency ω and polarization p.Λ=vτ is the phonon mean free path. For the multiscale simulation, it should be noted that it is in general very challenging to solve the three-dimensional (3D) spectral dependent BTE, especially using deterministic methods. Here, to tackle this issue, one can deploy a recently developed variance-reduced Monte Carlo (VRMC) method to solve BTE for the 3D experimental geometry. In VRMC method, phonon bundles are initialized in the computational domain, and then proceeded following “advection-sampling-scattering” procedures. In the advection procedure, the phonon bundles are moved under group velocity. In the sampling procedure, the energy carried by the phonon bundles are sampled. In the scattering procedure, the frequencies of the phonon bundles are redistributed based on the spectral distribution of the specific heat. To determine the hot spot temperature, we calculate the temperature response to a heat pulse and integrate the response from t=0 to infinity. All the material's spectral properties for the input into the BTE simulation come from ab initio calculations and experiments.

FIGS. 4a to 4d illustrate example aspects of device interface integration of BAs cooling substrate and GaN transistors for high-performance thermal management versus transistor channel length scaling and power density: Experimental measurements and multiscale modeling of hot spot temperature in operating HEMTs.

FIG. 4b shows the hot spot temperature as a function of the scaling heating sizes (solid line). As expected, with reducing the heating width from 100 μm to 100 nm, the hot spot temperature increases dramatically due to the increased packing density. It was also noticed that the ballistic heat transfer becomes substantial for heat spots of small sizes, so that Fourier's law result deviates significantly from the BTE calculation, i.e., representing the practical heating behavior. When the heating width is large, the result of Fourier's law is consistent with the BTE. But when heating source width is smaller than 1 μm, the hot spot temperature by the BTE is much higher compared with Fourier's law, and such difference between the BTE and Fourier's law increases dramatically with the width decrease of the heating source. Fundamentally, the ballistic transport takes place when the heated spot size is smaller than the mean free paths, and here it occurs for a heating source width on the order of ˜1 μm, which is consistent with our previous study of phonon mean free paths. The result clearly shows that at the nanoscale, the ballistic transport will significantly increase the overheating issue over classical theory prediction. Importantly, the hot spot temperatures are compared between the GaN-BAs device and the state-of-the-art GaN-diamond device (FIG. 4b). It clearly shows that for the whole range of scaling lengths, BAs is inherently superior to diamond for heat dissipation. For example, with a 1 μm heating width, the hot spot temperature for BAs is 38% lower than that of diamond, the current best reported in literature for high power cooling. Significantly, the results demonstrate that the high G value between GaN and BAs (250 MW/m²K), together with its high thermal conductivity (1300 W/mK), substantially improves heat dissipation, and represent the record high heat dissipation performance beyond state of the arts. The result underscores the promise of using BAs for thermal management in nanoscale electronic devices.

Finally, developed was the device integration with high-electron-mobility transistor (HEMT) and experimentally measured the operating HEMT devices for performance comparison between different cooling substrates, i.e. BAs, diamond, and SiC. To make a fair comparison, the HEMTs are fabricated using the same AlGaN/GaN epitaxial layers and device layout (Methods). FIGS. 4a and 4c show SEM images of an example fabricated HEMTs device according to embodiments integrated on top of a BAs substrate. In FIG. 4d, measured was the hot spot temperature rise during the operating AlGaN/GaN HEMT as a function of power densities and plotted was the results in comparison between different cooling substrates. The measurement result clearly shows that, under the same conditions, the device cooling performance for BAs is significantly exceeding that for diamond and SiC. For example, at a transistor power density of ˜15 W/mm, the hot spot temperature rise is ˜60 K for GaN-BAs, substantially lower than the temperature rise for GaN-diamond (˜110 K) and GaN-SiC devices (˜140 K). These experimental measurements on real HETM devices under the same device layout and operational conditions clearly verifies the modeling prediction and intrinsic advantage of using BAs for high-performance thermal management.

In summary, the present Applicant reports for the first time the heterogeneous integration of the emerging HTC materials for high-performance thermal management. This ultrafast spectroscopy measurement and atomistic theory calculation demonstrated that interface thermal transport is significantly improved with BAs and BP in comparison to the state of the arts. Replacing diamond with BAs, developed was the first BAs-GaN structure using metamorphic heteroepitaxy growth and measured its thermal boundary conductance to be over 8 times improvement than a typical diamond-GaN interface. With ab initio and atomistic calculations, the intrinsic enhancement in heat dissipation is verified due to the phonon band structures, under varied conditions including Radiation limit, diffuse scattering calculation, and ab-initio MD simulations. The hot spot temperatures of GaN devices integrated with different cooling substrates are examined for both diffusive and ballistic regimes with length scaling from 100 μm to 100 nm, showing the superior thermal management performance of BAs. The direct experimental measurement of operating AlGaN/GaN HEMTs confirms the clear advantage in reducing hot spot temperatures using BAs versus diamond or SiC as the cooling substrate. Device integration of the new materials could revolutionize the future technological paradigm of electronics packaging and extend the roadmap of high power electronics.

### Example Fabrication Methods

High thermal conductivity substrates and metal films: BP and BAs samples were synthesized by epitaxial growth and flux growth methods respectively, as descripted in previous reports (e.g. Kang, J. S. et al., “Thermal Properties and Phonon Spectral Characterization of Synthetic Boron Phosphide for High Thermal Conductivity Applications,” Nano Lett. 17, 7507-7514 (2017); and Kang, J. S. et al., “Experimental observation of high thermal conductivity in boron arsenide,” Science 578, 575-578 (2018)). Different metal films (Al, Au, Ni, Pd, Pt, and Ti, Kurt J. Lesker, 99.999%) were deposited on the samples using e-beam evaporator under high vacuum (<10-7 Torr) with ˜1 Å/s deposition rate. Heteroepitaxy integration of BAs and GaN. GaN samples including both bare GaN film and AlGaN/GaN HEMTs are integrated with BAs for the study. A thin oxide layer was deposited on each surface of the BAs and GaN samples using the atomic layer deposition (ALD) process (Fiji F200, Cambridge Nanotech). Trimethylaluminum was used as precursor to deposit 10 cycles Al₂O₃ at 473 K. Oxygen plasma treatment was applied to the oxide layers. Example process details can be found in “Hu, Y. et al., “A Ge/Si heterostructure nanowire-based double quantum dot with integrated charge sensor,” Nat. Nanotechnol. 2, 622-5 (2007). BAs and GaN samples were mechanically transferred and bonded together through the oxide layers. The bonded BAs-GaN samples were annealed at 773 K in vacuum to form the high-quality interfaces for measurements. To examine the thermal stability, the integrated samples were measured with thermal cycling between room temperature and 600 K for over ten times; all the samples were measured with consistent results and no appreciable degradation.

GaN-BAs devices and AlGaN/GaN-BAs HEMT devices: GaN-on-Si wafer consisting of a ˜1 μm-thick AlGaN transition layer, 1 μm-thick GaN buffer layer, and 20 nm AlGaN top barrier layer, was used as the device layer. The HEMT devices with two fingers, 100 μm-wide and 34 μm gate pitch were fabricated using e-beam lithography (JSM-6610, JEOL). Rapid Thermal Annealing (RTA, RTP 600xp, Modular Process Technology) at 973K for 30 s under forming gas (98% argon and 2% hydrogen) was used to form ohmic contact. The Si substrate and AlGaN epitaxial transition layer, used to accommodate the lattice mismatch during GaN-on-Si growth, were selectively etched out by using HNO₃:HF:CH₃COOH (5:4:1) mixture and AZ400K developer, respectively. The exposed clean and smooth GaN surface was bonded with BAs substrate following the heteroepitaxy integration process. The HEMT epitaxial layers, device layout, I-V characteristics and operation conditions for GaN-BAs are consistent with the reported GaN-diamond and GaNSiC devices, with the understanding that this is an evolving technology. Example details regarding transistor fabrication and I-V transport characterizations that can be used in the present embodiments have been described by the present Applicant and others in Ke, M. et al., “Complementary doping of van der Waals materials through controlled intercalation for monolithically integrated electronics,” Nano Res. 13, 1369-1375 (2020), Nguyen, H. D. et al., “High-performance field emission based on nanostructured tin selenide for nanoscale vacuum transistors,” Nanoscale 11, 3129-3137 (2019), Hu, Y. et al., “Sub-100 nanometer channel length Ge/Si nanowire transistors with potential for 2 THz switching speed,” Nano Lett. 8, 925-930 (2008), and Xiang, J. et al. “Ge/Si nanowire heterostructures as high-performance field-effect transistors,” Nature 441, 489-493 (2006).

Transmission electron microscopy (TEM) measurement. TEM sample of BAs and GaN heterostructures were prepared by using a focused ion beam (FIB) machine (Nova 600, FEI). The sample was cut by FIB into small pieces: 5 μm×5 μm×2 μm (width×height×thickness), and transferred to a TEM sample holder (PELCO FIB Lift-Out, Ted Pella) with a nanomanipulator. The heterostructure sample was further milled by FIB until the sample thickness was thin enough (<100 nm) to be traversed by the electron beam for effective TEM imaging. After FIB, the sample was transferred to an aberration-corrected scanning TEM (Grand ARM, JEOL) for imaging. Annular bright field images were taken under 300 keV acceleration voltage. The measured data and atomic-resolution TEM images were processed with the Gatan TEM software.

Raman Spectroscopy. Raman thermography was performed using micro Raman spectroscopy (inVia, Renishaw) under 488 nm laser excitation with 2400/mm grating. The laser was polarized and backscattered with Leica DM2500 optical system. We used 50×/0.75 numerical aperture objective lens and measured lateral spatial resolution was 0.5 μm. In addition, calibrations on temperature, thermoelastic stress, and electrical field in GaN HEMTs were carefully performed to determine the accurate temperatures via Raman measurements.

### CONCLUSIONS

Thermal management has been arguably the most critical technology challenge for modern electronics. Recent efforts in addressing this challenge lead to the discovery of new semiconductor materials with ultrahigh thermal conductivity, but their electronic device integration and interface energy transport have yet to be demonstrated. Here is presented a novel heterogeneous integration of boron arsenide (BAs) and boron phosphide (BP) with metals, semiconductors, wide-bandgap gallium nitride (GaN), and HEMT devices for high-performance thermal management. Ultrafast optical spectroscopy measurements and atomistic phonon theory calculations have verified the unprecedented combination of record-high high thermal conductivity and thermal boundary conductance due to the unique phonon band structures. The present Applicant successfully developed a practical integration and atomic structural characterization of GaN-on-BAs structure for passive cooling of RF transistors, and measured a high thermal boundary conductance of 250 MW/m²K. Furthermore, comparison of the device-level hot spot temperatures of GaN transistors with length-dependent scaling from 100 μm to 100 nm in both diffusive and ballistic transport regimes, shows that the power cooling performance of BAs intrinsically exceeds that of diamond devices and the state of the arts. Importantly, experimental measurement of operating AlGaN/GaN HEMT devices confirms the substantially reduced hot spot temperature and clear advantage for using BAs versus diamond or silicon carbide as cooling substrate. This study represents a significant progress towards device integration of emerging high thermal conductivity semiconductors for advanced thermal management and establishes a benchmark performance to extend the roadmap for high power electronics.

Since the integration and device performance of the BAs-WBG, BAS-UWBG, BP-WBG, BP-UWBG were realized by the present Applicant for the first time, the present embodiments encompass the following broad applications: (1) All the device application through integration or inclusion of boron arsenide and boron phosphide with metals, semiconductors (Si, Ge, InP, InAs, GaAs), WBG (GaN, AlGaN, SiC) and UWBG materials (AlN, cBN, diamond, Ga₂O₃); (2) All the materials preparation, materials processing and integrations of boron arsenide and boron phosphide, including in the forms of its crystal, polycrystal, amorphous, or mixed with other materials and etc., and (3) all applications as a new materials or device platforms for all applications in electronics, RF technologies, photonics, optoelectronics, sensors, detectors, acoustics, etc. areas. It is expected that integration of BAs or BP with semiconductors, metals, WBG and UWBG materials will play significant role in modern technologies, including transistors, amplifiers, modulators, antennas, and all RF technologies.

### COMMERCIAL APPLICATIONS & COMPETITIVE ADVANTAGES

1) RF technologies: The present disclosure enables the development of semiconductor, WBG and UWBG device structures (e.g., novel heterostructures), and engineer/fabricate UWBG RF (microwave/millimeter wave) devices. Technology advances include material synthesis (epitaxial growth, growth techniques and characterization, materials/defect engineering), layer depositions, interconnections, layer architectures, wafer bonding, layer bonding, physics-based device design, contact engineering, surface and interface engineering, integral thermal management, high temperature operation, robustness, heterogeneous integration with other devices/materials systems, and other functionality/domains of WBG and UWBG materials/structures, including electronics, optoelectronics, optical, quantum, acoustic, multi-ferroic, and others.
2) Thermal applications: Any materials processing or integration to use boron arsenide and boron phosphide in any crystal, polycrystal, composite, or other structural forms to in direct or indirect contact with a heating source to conduct or collect heat is considered for this applications. Examples including computer, mobile devices, laptops, smart phones, amplifiers, radars, modulators, LEDs, displayers, vehicles, aircrafts, engines, converters, servers, inverters, turbines, traction, industrial motors, welders, utility, or any circuits heat dissipation or conduction. In addition, thermal applications using boron arsenide of its any crystal or structural forms for thermal energy conversion, storage, or thermal management is considered for this patent. With the continuously shrinking of electronic and photonic devices down to the nanoscale, heat generation in local hot spot is significantly increased and it reduces device performance and cause device failure. Current technology use aluminum oxide or silicon carbide as a substrate. However, instead of using copper, silicon, sapphire, Al₂O₃ and SiC, BAs substrate can serve more effective heat sink substrate because its thermal conductivity is one order of magnitude higher than currently used materials and can further increase device performance of electronics and photonics device.
3) Thermal interfaces and heat spreading substrate in electronics, optoelectronics, and photonics device applications. This patent also includes using any material forms of boron arsenide and boron phosphide for substrate or thermal interfaces for devices heat control, dissipation, or regulations. It includes using boron arsenide as substrate or between two or more segments, or together with other cooling substrates or liquid or gas cooling mediums, as long as the forms of boron arsenide or boron phosphide systems is used for heat conduction or spreadings. When two different materials contact together, additional thermal resistance is generated at the interface. In this case, heat is hard to across the interface. Current technology use thermal grease which is polymer mixed with silver nanoparticle to enhance heat transport at interface. However, thermal conductivity of thermal grease is still ˜1W/mK. BAs can help to increase thermal transport at the interface. If nanostructured BAs is applied at the interface with polymer, thermal transport at the interface will increase dramatically.
4) Electronics, photonics, optoelectronics, acoustics devices. In analog to silicon, this new material platform will be used for applications in electronics (transistors, sensors, circuits, memories, radars, computing chips, graphics, amplifiers, modulators, switches, etc.), and photonics (lasers, LEDs, displayers, lighting applications), optoelectronics (photodetectors, switches, antennas), as well as any possible applications as the modern materials (silicon, germanium, gallium nitride, gallium arsenide, indium phosphide, indium arsenide) have ever or to be demonstrated.

The herein described subject matter sometimes illustrates different components contained within, or connected with, different other components. It is to be understood that such depicted architectures are illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably coupleable,” to each other to achieve the desired functionality. Specific examples of operably coupleable include but are not limited to physically mateable and/or physically interacting components and/or wirelessly interactable and/or wirelessly interacting components and/or logically interacting and/or logically interactable components.

With respect to the use of plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general, such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Further, unless otherwise noted, the use of the words “approximate,” “about,” “around,” “substantially,” etc., mean plus or minus ten percent.

Although the present embodiments have been particularly described with reference to preferred examples thereof, it should be readily apparent to those of ordinary skill in the art that changes and modifications in the form and details may be made without departing from the spirit and scope of the present disclosure. It is intended that the appended claims encompass such changes and modifications.

1. A device comprising:
a high thermal conductivity substrate; and
one of a semiconductor, a wide bandgap (WBG) material, an ultrawide bandgap (UWBG) material, a metal film, an electronic component or a power device in contact with the high thermal conductivity substrate.

2. The device of claim 1, wherein the high thermal conductivity substrate comprises boron arsenide (BAs).

3. The device of claim 1, wherein the high thermal conductivity substrate comprises boron phosphide (BP).

4. The device of claim 1, wherein the metal film comprises one of Al, Ti, Ni, Pt, Pd and Au.

5. The device of claim 2, wherein the metal film comprises one of Al, Ti, Ni, Pt, Pd and Au.

6. The device of claim 3, wherein the metal film comprises one of Al, Ti, Ni, Pt, Pd and Au.

7. The device of claim 1,
wherein the WBG material comprises a wide-bandgap gallium nitride (GaN) integrated with the high thermal conductivity substrate.

8. The device of claim 7, wherein the wide-bandgap GaN comprises a GaN film.

9. The device of claim 7, wherein the wide-bandgap GaN comprises a high-electron-mobility transistor (HEMT).

10. The device of claim 9, wherein the HEMT comprises a ALGaN/GaN structure.

11. The device of claim 1,
wherein the semiconductor comprises one or more of Si, Ge, InP, InAs and GaAs.

12. The device of claim 1,
wherein the UWBG material comprises one or more of AlN, c-BN, diamond and Ga₂O₃.

13. A method comprising:
forming a structure by performing a heterogeneous integration of one or more of boron arsenide (BAs), boron phosphide (BP), a metal, a semiconductor, a wide-bandgap material, an ultra-wide bandgap material and a HEMT.

14. The method of claim 13, wherein forming the structure includes synthesizing a BP sample by epitaxial growth.

15. The method of claim 13, wherein forming the structure includes synthesizing a BAs sample by flux growth.

16. The method of claim 13, wherein forming the structure includes depositing the metal on a sample of one of the BP and the BAs.

17. The method of claim 16, wherein the metal comprises one of Al, Au, Ni, Pd, Pt, and Ti.

18. The method of claim 13, wherein the wide-bandgap material comprises GaN.

19. The method of claim 18, wherein forming the structure includes integrating a GaN film with a sample of one of the BAs and BP.

20. The method of claim 13, wherein the wide-bandgap material and the HEMT are comprised by a AlGaN/GaN HEMT.
